(19) United States
(12) Patent Application Publication
(10) Pub. No.: US 2007/0232089 A1
(43) Pub. Date: Oct. 4, 2007

(54) Bridge modules for connecting plural groups of electronic modules

(75) Inventor: Laurie P. Fung, Pleasanton, CA (US)

Correspondence Address: TROP PRUNER & HU, PC, 1616 S. VOSS ROAD, SUITE 750, HOUSTON, TX, 77057-2631, US

(73) Assignee: Nortel Networks Limited, St. Laurent (CA)

(21) Appl. No.: 11/394,815

(22) Filed: Mar. 31, 2006

(51) Int. Cl. H05K 1/00

(52) U.S. Cl. 439/65

(57) ABSTRACT

A first group of electronic modules has a first orientation, and a second group of electronic modules has a second orientation different from the first orientation. The first group and second group of electronic modules are connected through a midplane board. Bridge modules are electrically connected to the first and second groups of electronic modules to electrically connect devices of at least some of the first and second groups of electronic modules, where the bridge modules are different from the electronic modules in each of the first and second groups.

### TECHNICAL FIELD

The invention relates generally to bridge modules for electrically connecting plural groups of electronic modules having different orientations.

### BACKGROUND

Traditionally, computer systems (such as personal computers, servers, and so forth) and communications nodes (such as switching systems, routing systems, and so forth) include multiple electronic modules that are mounted on a backplane structure, in the form of a circuit board. The backplane structure (also referred to as a backplane board) has connectors for receiving the electronic modules, which can be integrated circuit devices or other circuit boards (sometimes referred to as daughter boards or cards). The backplane board typically does not allow for high densities of electronic modules, since the backplane board allows electronic modules to be mounted only on one side of the backplane board.

To address this issue, midplane boards have been implemented to allow electronic modules to be mounted to both main surfaces of the midplane board. In one arrangement, connectors are provided on both the main surfaces of the midplane board to receive corresponding electronic modules. Signal traces are provided in the midplane board to electrically connect the electronic modules on both sides of the midplane board. An issue associated with this midplane board arrangement is that a large quantity of signal traces are required, which often leads to many signal trace layers in the midplane board. Such a midplane board arrangement has various issues, including increased complexity that leads to increased costs, signal cross-talk issues, limited communications speeds in the signal traces of the midplane circuit board, and other issues.

A second arrangement of midplane boards include midplane boards that have openings formed in the midplane boards such that connectors of electronic modules on one side of the midplane board can directly plug into connectors of electronic modules on another side of the midplane board. This arrangement simplifies the design of the midplane board and enhances signal communications speeds. However, an issue associated with the use of this second arrangement of midplane boards is that systems that employ this type of midplane board have to be fully-loaded systems (in which all electronic modules have to be included) to allow proper communication between electronic modules on the two sides of the midplane board. Having to provide fully-loaded systems increases costs to customers, since all electronic modules have to be included whether or not the customers actually need the capacities provided by the fully-loaded systems.

### SUMMARY

In general, according to an embodiment, an apparatus comprises a first group of electronic modules having a first orientation, the first group of electronic modules having respective devices. The apparatus further includes a midplane board and a second group of electronic modules having respective devices and a second orientation different from the first orientation, the second group of electronic modules connected to the first group of electronic modules through the midplane board. The apparatus further includes bridge modules electrically connected to the first and second groups of electronic modules to electrically connect devices of at least some of the first and second groups of electronic modules.

Other or alternative features will become apparent from the following description, from the drawings, and from the claims.

### BRIEF DESCRIPTION OF THE DRAWINGS

FIG. 1 illustrates an example of a fully-loaded system that includes a midplane board arrangement.

FIG. 2 illustrates a partially-loaded system having a midplane board and a first group and second group of boards, in which some of the boards in the first and second groups have broken links.

FIG. 3 illustrates a midplane board having openings to allow the first and second groups of boards to connect to each other, in accordance with an embodiment.

FIG. 4 is a schematic diagram of the partially-loaded system of FIG. 2.

FIG. 5 illustrates a partially-loaded system having the midplane board, the first and second groups of boards, and bridge boards to reconnect the broken links of the system of FIG. 2, in accordance with an embodiment.

FIGS. 6 and 7 illustrate bridge boards used in the partially-loaded system of FIG. 5.

FIG. 8 is a schematic diagram of the partially-loaded system of FIG. 5 that includes the bridge boards.

FIG. 9 illustrates a partially-loaded system having a midplane board, first and second groups of boards, and bridge boards to reconnect broken links, in accordance with another embodiment.

### DETAILED DESCRIPTION

In the following description, numerous details are set forth to provide an understanding of the present invention. However, it will be understood by those skilled in the art that the present invention may be practiced without these details and that numerous variations or modifications from the described embodiments may be possible.

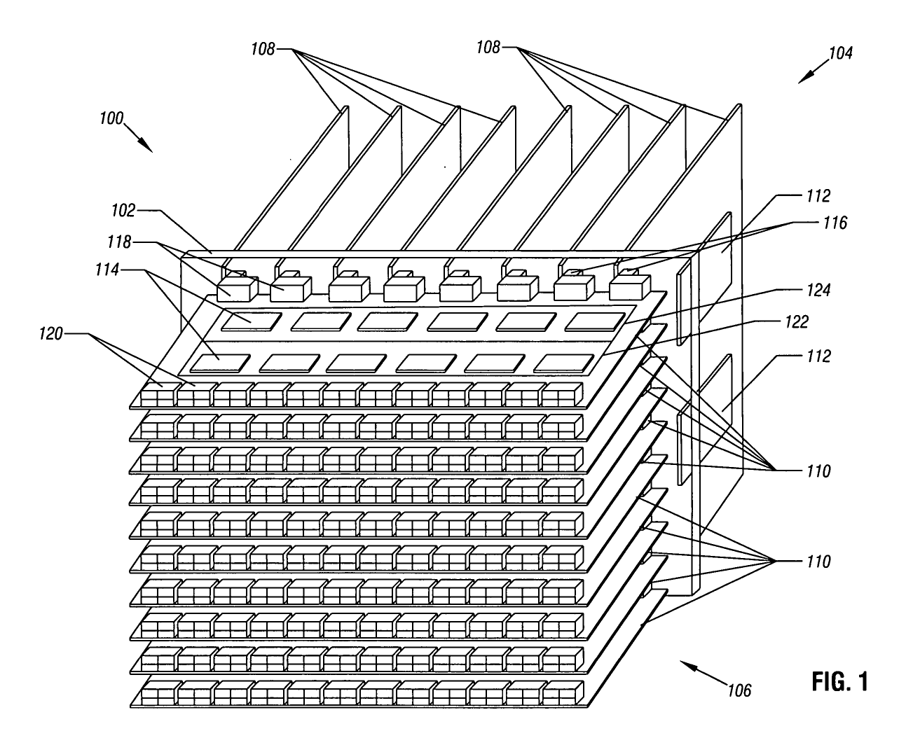

FIG. 1 illustrates an example system 100 that has a midplane board 102, a first group 104 of electronic modules 108 provided on one side of the midplane board 102, and a second group 106 of electronic modules 110 provided on the other side of the midplane board 102. A “midplane board” refers to any structure that enables electronic modules provided on two opposite sides of the midplane board to be connected to each other through the midplane board. In other words, the midplane board has a first main surface on (proximate) which the first group of electronic modules are arranged, and a second main surface (opposite the first main surface) on (proximate) which the second group of electronic modules are arranged. Note that the midplane board 102 has been shown as being transparent to better illustrate the components behind the midplane board 102. Normally, the midplane board 102 is formed of circuit board materials that are non-transparent.

The midplane board 102 is implemented as a circuit board with openings provided in the circuit board to allow electrical connection to be achieved between the first group 104 of electronic modules 108 and second group 106 of electronic modules 110. The midplane board 102 can have one or multiple layers of power and ground planes, where each power plane is an electrically conductive layer that is connected to a power voltage, and each ground plane is an electrically conductive layer connected to a reference voltage, such as ground. In some implementations, the midplane board 102 can also have signal traces for communication of signals.

As depicted in the example of FIG. 1, each electronic module 108 in the first group 104 includes circuit boards each having one or more electronic devices 112 mounted on the respective circuit board 108. The circuit boards 108 are also referred to as cards or daughter boards. Similarly, the electronic modules 110 include circuit boards (cards or daughter boards) each having one or more electronic devices 114 mounted on the respective circuit board 110.

In the ensuing discussion, reference is made to the first group 104 of “circuit boards” 108 and the second group 106 of “circuit boards” 110. Although reference is made to “circuit boards” in this discussion, it is to be understood that some embodiments can be applied to other types of electronic modules, such as integrated circuit (IC) devices (e.g., microprocessors, memory modules, and so forth).

The circuit boards 108 in the first group 104 generally have a first orientation (a vertical orientation as depicted in FIG. 1), while the circuit boards 110 in the second group 106 generally have a second orientation (a horizontal orientation as depicted in FIG. 1). The circuit boards 108 and circuit boards 110 are thus generally orthogonal to each other. “Generally orthogonal” refers to an orientation that is substantially perpendicular (within tolerances of manufacturing or assembly technologies). In other embodiments, rather than an orthogonal relationship between the circuit boards 108 and circuit boards 110, other different relative orientations can be provided, such as circuit boards 108 and circuit boards 110 being provided at some slanted angle (e.g., 45° angle) with respect to each other.

The system 100 can be any type of electronic system, such as a computer system (e.g., a processing server, a personal computer, a storage server, and so forth) or a communications system (e.g., a switch system, a router system, and so forth), or other type of system. In the example of FIG. 1, the illustrated system 100 is a communications system in which the first group 104 of circuit boards 108 are part of a distributed switch fabric, where each circuit board 108 is a switch fabric card having electronic devices 112 to perform switching functions (such as Ethernet switching functions). The second group 106 of circuit boards 110 include input/output (I/O) line interface cards for connection to other equipment, such as other switches, customer premise equipment (e.g., telephone handsets), or other types of devices. In alternative embodiments, the circuit boards 108 and 110 include other types of electronic devices for performing other functions, such as circuit boards containing central processing units (CPUs), storage devices, and so forth.

Each of the circuit boards 110 in the second group 106 has a corresponding set of connectors 118 arranged along an edge of the respective circuit board 110 (the edge facing the midplane board 102), and each of the circuit boards 108 has a corresponding set of connectors 116 along an edge of the respective circuit board 108 (the edge facing the midplane board 102).

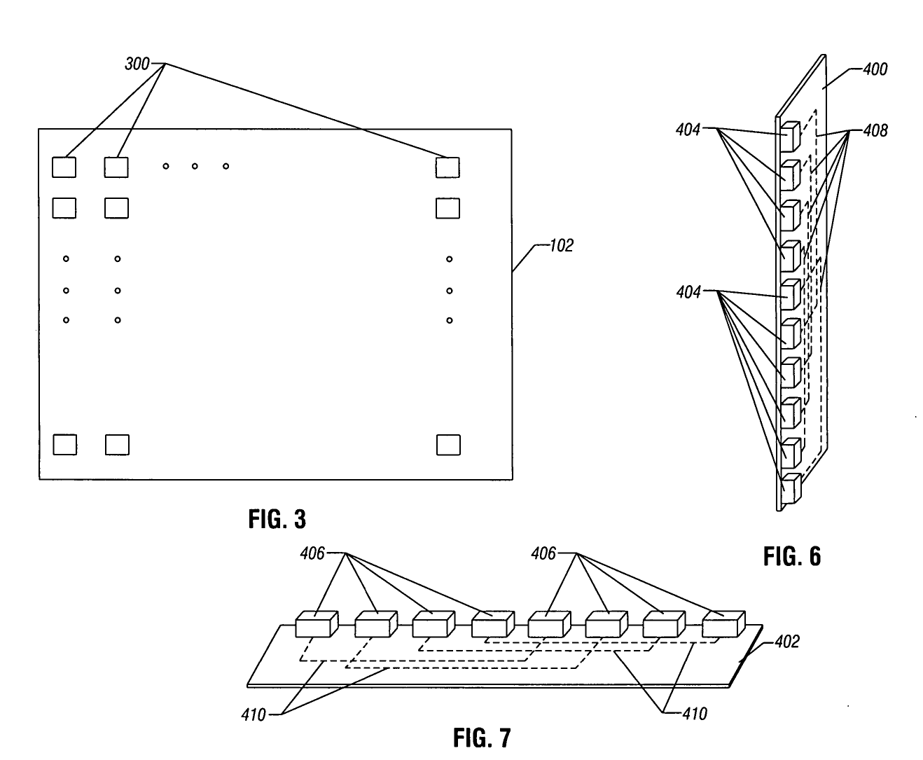

As depicted in FIG. 3, the midplane board 102 has multiple openings 300 to allow one or both of the connectors 116, 118 to pass through the thickness of the circuit board 102 to allow corresponding pairs of connectors 116, 118 to be directly mated together (both physical and electrical mating).

Due to the generally orthogonal arrangement of the circuit boards 108 with respect to the circuit boards 110, the connectors 116 of one circuit board 108 are mated to corresponding connectors 118 of multiple circuit boards 110. In the FIG. 1 implementation, the connectors 116 in one column (in the vertical direction) along one circuit board 108 are electrically connected to a respective column of connectors 118 on respective different circuit boards 110. Similarly, a row of connectors 118 on one circuit board 110 is connected to a respective row of connectors 116 of corresponding different circuit boards 108.

In the example of FIG. 1, each I/O line interface card 110 further has I/O connectors 120 for electrical connection to other devices, as mentioned above. Also, the electronic devices 114 on each I/O line interface card 110 are divided into a line interface section 122 for interfacing the I/O connectors 120 and a fabric interface section 124 for interfacing the switch fabric cards 108. In other examples, other electronic devices are provided on each circuit board 110.

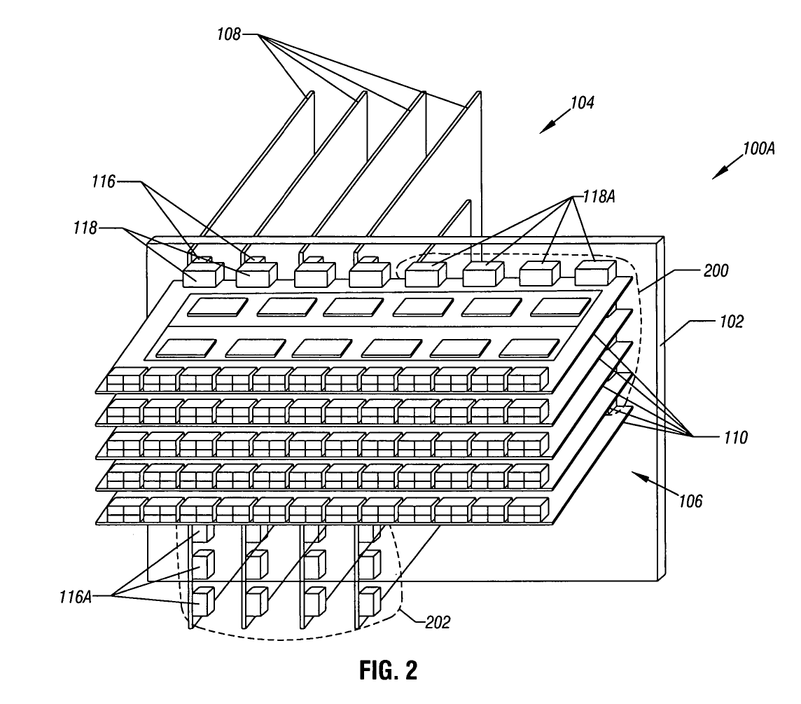

The system 100 depicted in FIG. 1 is a fully-loaded system in which the maximum number of circuit boards 108 and the maximum number of circuit boards 110 are provided. Although specific numbers of circuit boards 108 and 110 are depicted, note that larger or smaller numbers of circuit boards 108 and 100 can be provided in other example implementations. To reduce costs to customers, it is desirable for a manufacturer of the system 100 to be able to reduce the number of circuit boards provided in the system 100. For example, a partially-loaded system 100A is depicted in FIG. 2, in which some of the circuit boards 108 in the first group 104 and some of the circuit boards 110 in the second group 106 have been omitted. However, as indicated by dashed boxes 200 and 202 in FIG. 2, a subset 118A of the connectors 118 of the circuit boards 110 in the second group 106 are no longer connected to any circuit boards 108 in the first group 104 as a result of the missing circuit boards 108 in the system 100A. Similarly, a subset 116A of the connectors 116 on circuit boards 108 in the first group 104 are no longer connected to circuit boards 110 in the second group 106 as a result of the missing circuit boards 110 in the system 100A. These subsets 116A, 118A of connectors are referred to as floating (un-mated or un-connected) connectors 116A, 118A. The floating connectors 116A, 118A cause “broken links” (electrical connections that have been broken) between devices on the circuit boards 108 and 110. Presence of the floating connectors 116A, 118A would thus result in at least a portion of the electronic devices mounted on the circuit boards 108 and 110 to not function because they are not properly connected to other devices.

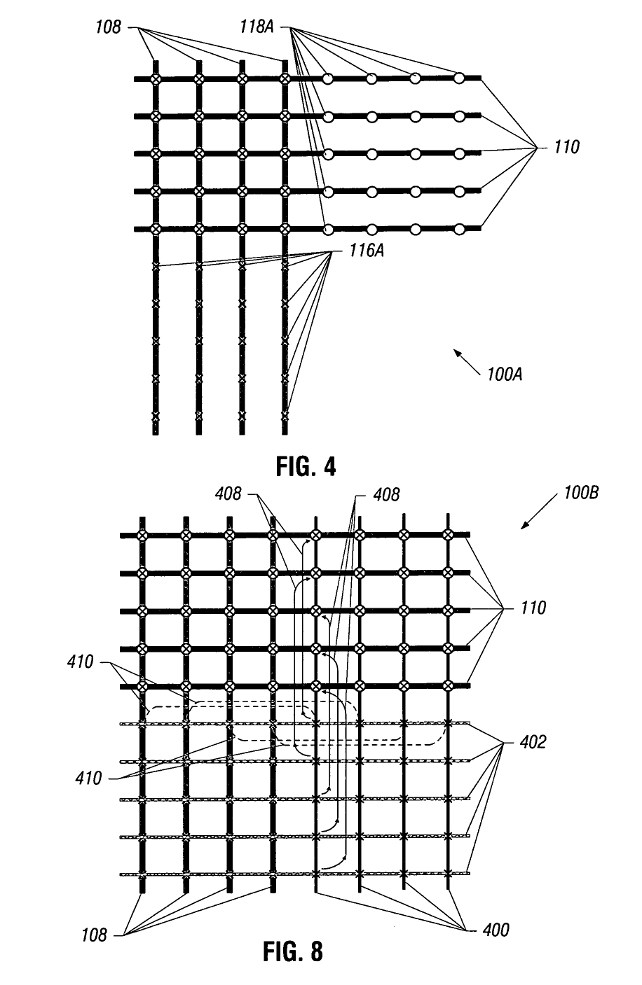

FIG. 4 shows the floating connectors 118A (represented as empty circles) of the circuit boards 110, and the floating connectors 116A (represented as “X”s) of the circuit boards 108. In FIG. 4, the circles that are filled with corresponding “X”s represent mated connectors 116, 118.

To re-connect the broken links in a partially-loaded system, bridge boards (also referred to as “bridge cards”) are used. A “bridge board” or “bridge card” refers to a circuit board or card that is different from the circuit boards 108 and 110. The circuit boards 108 and 110 in respective first and second groups 104 and 106 are considered functional circuit boards that have electronic devices to perform their intended functions (e.g., switching function, line interface function, processing function, storage function, etc.). On the other hand, a bridge board or bridge card does not include the functional electronic devices for performing the functions of the functional circuit boards 108, 110. In some embodiments, each bridge board includes signal traces (without the functional electronic devices), which signal traces are used for the purpose of re-connecting the floating connectors 116A, 118A to corresponding circuitry to remove the broken links and to enable proper functioning of the electronic devices coupled to the broken links.

More generally, reference is made to a “bridge module,” which includes bridge boards, bridge cards, other types of electronic modules for performing bridging, and so forth. In general, a “bridge module” refers to any module that performs electrical bridging between electronic modules provided on two opposite sides of a midplane board.

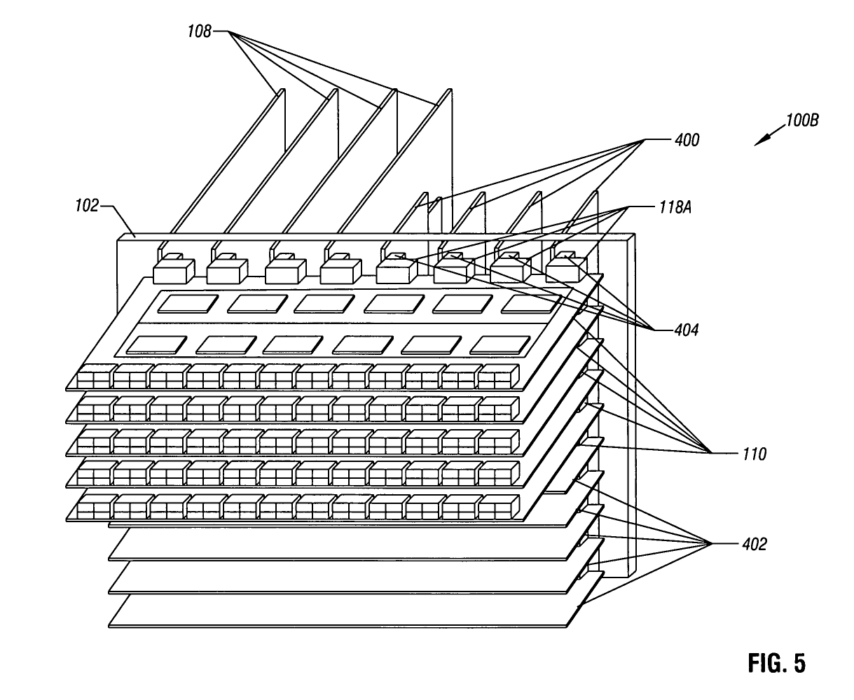

As depicted in FIG. 5, the bridge boards include first group bridge boards 400 arranged in the same orientation as the circuit boards 108 (the generally vertical orientation), and second group bridge boards 402 that are arranged in the same orientation as the circuit boards 110 (the generally horizontal orientation). Each bridge board 400 is used for replacing or substituting for a missing circuit board 108, and each bridge board 402 is used for replacing or substituting for a corresponding missing circuit board 110. The partially-loaded system including the bridge boards 400 and 402 is referred to as a partially-loaded system 100B.

A bridge board 400 according to one embodiment is depicted in FIG. 6, and a bridge board 402 according to one embodiment is depicted in FIG. 7. Each bridge board 400 includes connectors 404 (which are identical to the connectors 116 of each circuit board 108). Similarly, the bridge board 402 has a set of connectors 406 that are identical to connectors 118 used on each circuit board 110. The connectors 404 are attached to the bridge board 400. The connectors 406 are attached to the bridge board 402.

As further depicted in FIG. 6, multiple groups of signal traces 408 are provided in the bridge board 400, where each signal trace group 408 connects a respective pair of connectors 404. Each group 408 refers to a group of one or more signal traces. In the example of FIG. 6, ten connectors 404 are shown, in which a first signal trace group 408 electrically connects the first connector 404 (the uppermost connector) to the sixth connector 404 (sixth from the uppermost connector); a second signal trace group 408 electrically connects the second connector 404 (second from the uppermost connector) to the seventh connector 404 (seventh from the uppermost connector); a third signal trace group 408 electrically connects the third connector 404 to the eighth connector 404; a fourth signal trace group 408 electrically connects the fourth connector 404 to the ninth connector 404; and a fifth signal trace group 408 electrically connects the fifth connector 404 to the tenth connector 404. The number of connectors and signal traces are provided for example purposes. In other implementations, signal trace groups 408 can connect other combinations of connectors 404. Also, instead of just connecting a pair of connectors, each signal trace group 408 can connect more than two connectors 404.

In FIG. 7, the bridge board 402 is depicted as having eight connectors 406 with corresponding groups of signal traces 410 electrically connecting corresponding pairs of connectors 406. In the example of FIG. 7, a first signal trace group 410 electrically connects the first connector 406 (the rightmost connector) to the fifth connector 406 (fifth from the rightmost connector); a second signal trace group 410 electrically connects the second connector 406 (second from the rightmost connector) to the sixth connector 406; a third signal trace group 410 electrically connects the third connector 406 to the seventh connector 406; and a fourth signal trace group 410 electrically connects the fourth connector 406 to the eighth connector 406 (the leftmost connector). In other implementations, a larger or smaller number of connectors 406 and/or signal trace groups 410 can be used instead. Also, the signal trace groups 410 can electrically connect other combinations of connectors 406.

FIG. 8 is a schematic diagram showing the partially-loaded system 100B of FIG. 5. In the partially-loaded system 100B of FIGS. 5 and 8, the floating connectors 118A (FIG. 4) are mated directly through the midplane board to corresponding connectors 404 (FIG. 6) of bridge boards 400, and the floating connectors 116A (FIG. 4) are mated directly through the midplane board to corresponding connectors 406 (FIG. 7) of bridge boards 402. If the system 100B is considered to be divided into four quadrants in the view of FIG. 8, then the connections are as follows: (1) in the left, upper quadrant, connectors 116 of circuit boards 108 are mated to respective connectors 118 of circuit boards 110; (2) in the right, upper quadrant, connectors 118A of circuit boards 110 are mated to respective connectors 404 of the bridge boards 400; (3) in the left, lower quadrant, connectors 116A of the circuit boards 108 are mated to respective connectors 406 of bridge boards 402; and (4) in the right, lower quadrant, connectors 404 of bridge boards 400 are mated directly through the midplane board to corresponding connectors 406 of bridge boards 402.

The provision of the bridge boards 400, 402 in the partially-loaded system 100B allows a signal originated at an electronic device on the circuit board 110 that is connected to a floating connector 118A to be communicated through a path that includes: a respective connector pair 118A, 404 (to connect the circuit board 110 to the respective bridge board 400 through the midplane board); a signal trace group 408 on the respective bridge board 400; a respective connector pair 404, 406 (to connect the bridge board 400 to a respective bridge board 402 through the midplane board); a respective signal trace group 410 on the bridge board 402; and a respective connector pair 406, 116A (to connect the bridge board 402 to a respective circuit board 108 through the midplane board). A similar return path is followed for a signal originated at an electronic device of a circuit board 108 that is connected to a floating connector 116A.

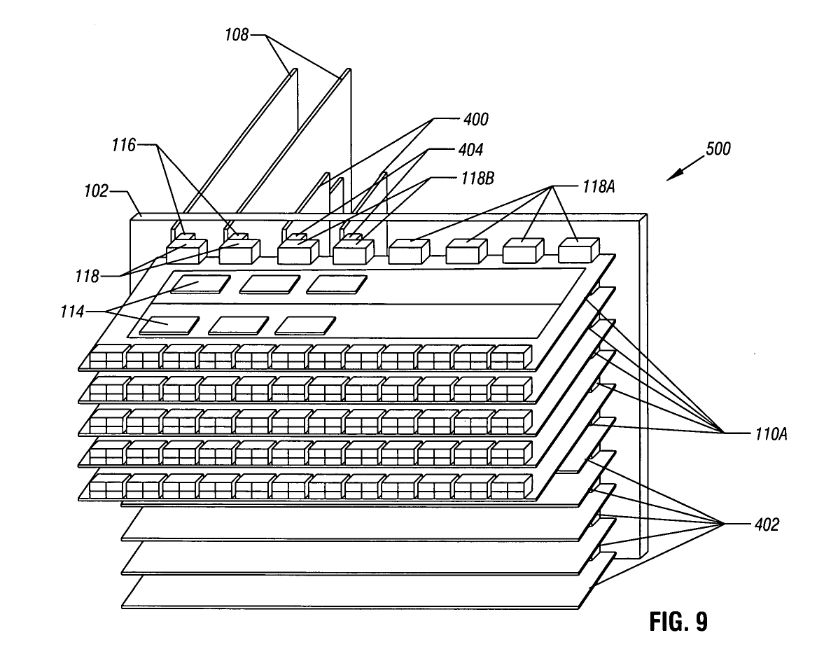

FIG. 9 shows a partially-loaded system 500 according to another embodiment, which shows a lower cost configuration than the configuration depicted in FIG. 5. In the system 500, note that circuit boards 110A have a fewer number of electronic devices 114 than the circuit boards 110 of FIG. 5. There are two groups of floating connectors 118: floating connectors 118A that are not connected to electronic devices on the circuit boards 110A; and floating connectors 118B that are connected to electronic devices on the circuit boards 110A. In this arrangement, the connectors 118A remain floating (in other words, bridge boards 400 are not connected to the floating connectors 118A). Rather, bridge boards 400 are connected to floating connectors 118B to compete electrical circuits for devices connected to the floating connectors 118B.

By being able to provide partially-loaded systems in which broken links are re-connected using bridge boards, manufacturers are able to provide lower cost systems to customers who may not need the full capacity of fully-loaded systems. As the needs of such customers change, additional functional boards can be subsequently added (in place of bridge boards) to the partially-loaded systems to increase the capacity of the systems, if desired.

While some embodiments have been disclosed with respect to a limited number of embodiments, those skilled in the art will appreciate numerous modifications and variations there from. It is intended that the appended claims cover such modifications and variations as fall within the true spirit and scope of the invention.

1. An apparatus comprising:
a first group of electronic modules having a first orientation, the first group of electronic modules having respective devices;
a midplane board;
a second group of electronic modules having respective devices and a second orientation different from the first orientation, the second group of electronic modules connected to the first group of electronic modules through the midplane board; and
bridge boards electrically connected to the first and second groups of electronic modules to electrically connect devices of at least some of the first and second groups of electronic modules,
wherein the bridge boards are different from the electronic modules in each of the first and second groups.

2. The apparatus of claim 1, wherein each of the electronic modules in the first group has respective first connectors, and each of the electronic modules in the second group has respective second connectors mated with corresponding first connectors through the midplane board.

3. The apparatus of claim 2, wherein at least a first one of the bridge boards comprises connectors mated with corresponding second connectors, and at least a second one of the bridge boards comprises connectors mated with corresponding first connectors.

4. The apparatus of claim 2, wherein the midplane board has openings to allow the second connectors to directly mate with corresponding first connectors.

5. The apparatus of claim 4, wherein the first group of electronic modules are on one main surface of the midplane board, and the second group of electronic modules are on an opposite main surface of the midplane board.

6. The apparatus of claim 1, wherein the bridge boards comprise a first bridge board having the first orientation, and a second bridge board having the second orientation.

7. The apparatus of claim 6, wherein the bridge boards are used to substitute for at least a missing one of the first group of electronic modules and a missing one of the second group of electronic modules.

8. The apparatus of claim 7, wherein the first group of electronic modules is a partially configured first group of electronic modules having less than a maximum number of first group electronic modules available in a fully-loaded configuration, and the second group of modules is a partially configured second group of electronic modules having less than a maximum number of second group electronic modules available in the fully-loaded configuration.

9. The apparatus of claim 1, wherein the first orientation is generally orthogonal to the second orientation.

10. The apparatus of claim 1, wherein the first group of electronic modules comprises switch fabric boards, and the second group of electronic modules comprises input/output line interface boards.

11. The apparatus of claim 1, wherein the bridge boards have connectors and signal traces to connect corresponding connectors of the first group electronic modules and second group electronic modules, the bridge boards configured without the devices of the electronic modules in the first group and the second group.

12. A system comprising:
a midplane board;
a first group of electronic modules provided on a first side of the midplane board, the first group of electronic modules having first connectors;
a second group of electronic modules provided on a second, opposite side of the midplane board, the second group of electronic modules having second connectors for mating with the first connectors through the midplane board,
wherein at least some of the first connectors are floating first connectors not connected to second connectors, and wherein at least some of the second connectors are floating second connectors not connected to first connectors;
a first bridge board arranged on the first side of the midplane board to connect to the floating second connectors through the midplane board; and
a second bridge board arranged on the second side of the midplane board to connect to the floating first connectors through the midplane board.

13. The system of claim 12, wherein the electronic modules of the first group and the first bridge board have a first orientation, and wherein the electronic modules of the second group and the second bridge board have a second, different orientation.

14. The system of claim 13, wherein the first and second orientations are generally orthogonal with respect to each other.

15. The system of claim 12, wherein the first bridge board has connectors identical to the first connectors, and wherein the second bridge board has connectors identical to the second connectors.

16. The system of claim 12, wherein the electronic modules of the first group include electronic devices for performing a first type of function, and the electronic modules of the second group include electronic devices for performing a second type of function,
wherein the first bridge board does not include electronic devices for performing the first type of function, and the second bridge board does not include electronic devices for performing the second type of function.

17. The system of claim 12, wherein each of the electronic modules in the first group and second group includes respective one or more devices, and wherein a particular device on a first electronic module in the first group that is connected to a floating first connector communicates with a corresponding electronic module in the second group through a signal path extending from the first electronic module through signal traces of the first and second bridge boards to the corresponding electronic module in the second group.

18. The system of claim 12, wherein the first group of electronic modules comprise circuit boards having devices to perform a first function, and the second group of electronic modules comprise circuit boards having devices to perform a second function.

19. A method comprising:
providing a partially-loaded system having a midplane board and first and second groups of electronic modules, wherein each of the first and second groups has less than a maximum number of electronic modules available in a fully-loaded system such that broken links are present;
arranging the first group of electronic modules in a first orientation;
arranging the second group of electronic modules in a second orientation different from the first orientation;
mating connectors of the first group of electronic modules with connectors of the second group of electronic modules through the midplane board; and
providing bridge boards that replace at least some of missing electronic modules in the first and second groups to re-connect the broken links.

20. The method of claim 19, wherein providing the bridge boards comprises providing at least a first bridge board having the first orientation and a second bridge board having the second orientation.
